(19) United States
(12) Patent Application Publication
(10) Pub. No.: US 2007/0001694 A1
(43) Pub. Date: Jan. 4, 2007

(54) On-die real time leakage energy meter

(76) Inventors: Sanjeev Jahagirdar, Folsom, CA (US); Jose Allarey, Davis, CA (US); Varghese George, Folsom, CA (US)

Correspondence Address: SCHWEGMAN, LUNDBERG, WOESSNER & KLUTH, P.A., P.O. BOX 2938, MINNEAPOLIS, MN, 55402, US

(21) Appl. No.: 11/173,147

(22) Filed: Jun. 30, 2005

(51) Int. Cl. G01R 31/02

(52) U.S. Cl. 324/760

(57) ABSTRACT

A method includes measuring a temperature for a portion of an electronic component, determining the voltage being applied to the portion of the component, and determining a leakage power for the component portion based on a measured temperature and determined voltage for the portion of the component. The method also includes measuring a temperature for another portion of the component, determining the voltage being applied to the other component portion, and determining a leakage power for the other component portion based on the measured temperature and determined voltage for the other portion of the component. The method also includes summing the leakage power for the portion with the leakage power for the other portion of the component.

### BACKGROUND

There is an industry push toward reducing power consumption in computer systems. Some government bodies even require energy compliant computing systems. The need for reducing power consumption of computers is especially keen for battery-operated mobile computing systems, such as laptops and notebook personal computers. Because the power source of mobile computers accounts for a significant percentage of the bulk and weight of the device, attempts have been made since the advent of laptops to reduce their power consumption.

In addition, there is an ever-constant push in the computing industry to deliver computing systems having increased performance. As microprocessors and other components within a computer system become faster and smaller, thermal management becomes an important factor in preventing device and component overheating or failure. Mobile computers, such as laptop and notebook computers, are not immune to the ever-constant push to deliver higher-performing systems. In mobile computing environments, thermal management is even a more important factor since the components are packed into a smaller housing. In other words, the heat generated is concentrated within the smaller housing and must be managed more effectively to prevent device component or failure. The amount of power consumed is related to the amount of heat generated by a computing system. Generally, the higher the amount of power consumed, the more heat that will be generated.

In order to effectively perform power management and thermal management in a computing system, the total power comsumption for selected components must be determined or estimated as accuarately as possible. The amount of active power used by a component cannot be used alone to project the total energy dissapated by a component or device, such as a microprocessor. Power comsumption includes not only the active power used by a component or device, but also includes the leakage power consumed by a component or device. Leakage power results from leakage current. Leakage current is inherent in devices or components that include transistors. Leakage current is current that conducts through a transistor even when the transistor is supposed to be off. In most circuit configurations, leakage current is undesirable because it consumes power without producing useful work. Leakage power consumption is inherent in semiconductor physics and is a product of the design methods used to create high speed processors. Leakage power consumption is caused by a voltage gradient across a junction within a semiconductor chip that causes current flow.

Currently, high performance devices are experiencing larger leakage currents as a percentage of total current consumption because of the greater number of transistors, with each transistor having a larger leakage current. The development of high performance devices or components, such as microprocessors, has led to increased leakage power consumption because higher frequency devices employ smaller transistors in larger numbers than ever before. The smaller the transistor channel length and oxide thickness, the greater the leakage power consumption.

### BRIEF DESCRIPTION OF THE DRAWINGS

FIG. 1 is a schematic view of a computing system, according to an example embodiment.

FIG. 2A is a schematic view of the component that includes a plurality of temperature sensors, according to an example embodiment.

FIG. 2B is a schematic view of the component that includes a plurality of temperature sensors, and a plurality of voltage sensors, according to an example embodiment.

FIG. 3 is a schematic view of a leakage meter, according to an example embodiment.

FIG. 4 is a schematic view of the voltage input device used to approximate the voltage input value to a leakage meter in the absence of a voltage sensor, according to an example embodiment.

FIG. 5 is a schematic view of a multiplier and accumulator, according to an example embodiment.

FIG. 6 is a flow diagram of a method determining the leakage power, according to an example embodiment.

FIG. 7 is a flow diagram of a method for determining the leakage power, for a number of voltage ranges and temperature ranges, according to an example embodiment.

FIG. 8 is a flow diagram of a method determining the leakage power, according to an example embodiment.

FIG. 9 is a schematic diagram of a machine accessible medium, according to an example embodiment.

### DESCRIPTION OF PREFERRED EMBODIMENTS

In the following detailed description of the preferred embodiments, reference is made to the accompanying drawings that form a part hereof, and in which are shown by way of illustration specific embodiments in which some embodiments of the invention may be practiced. It is understood that other embodiments may be utilized and structural changes may be made without departing from the scope of the present invention.

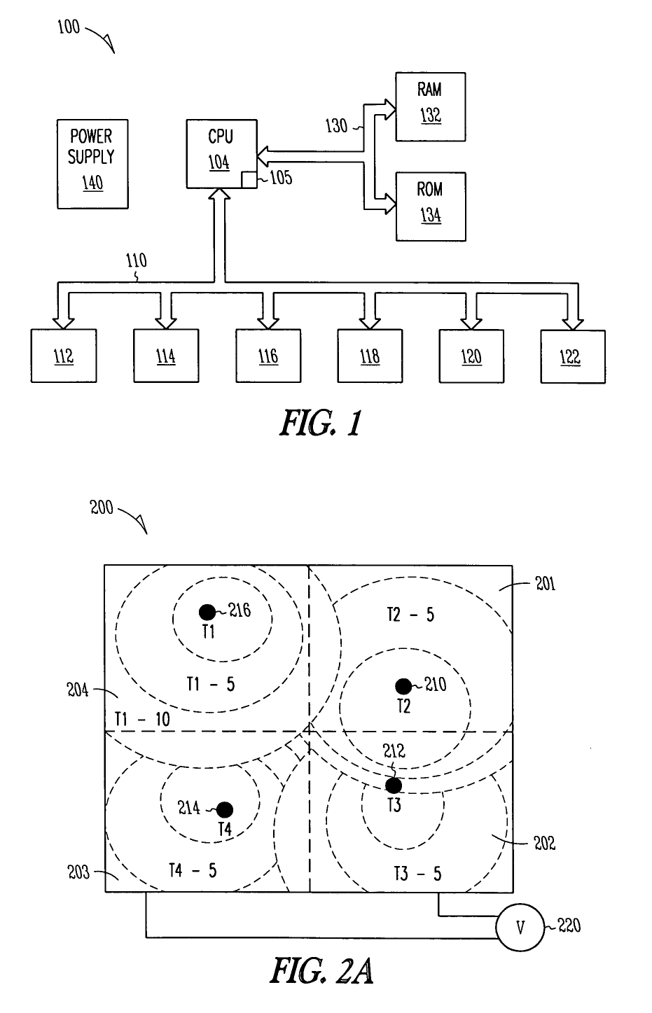

FIG. 1 is a schematic view of a system 100, such as a computer system 100, according to an example embodiment. The computer system 100 may also be called an electronic system or an information handling system and includes a central processing unit 104, a random access memory 132, a read only memory 134, and a system bus 130 for communicatively coupling the central processing unit 104, the random access memory 132 and the read only memory 134. The information handling system 100 also includes an input/output bus 110. One or more peripheral devices, such as peripheral devices 112, 114, 116, 118, 120, and 122 may be attached to the input output bus 110. Peripheral devices include hard disc drives, magneto optical drives, floppy disc drives, monitors, keyboards and printers, scanners, fax machines, or any other such peripherals. The information handling system 100 includes a power supply 140. In the case of a mobile information handling system 100, the power supply 140 can include a battery which delivers power at a specific level to the central processing unit 104, the random access memory 132, and the read only memory 134. In some embodiments, the battery also supplies power at a specific level to one or more of the peripherals 112, 114, 116, 118, 120, 122. A mobile information handling system 100, in some embodiments, also includes a transformer for transforming alternating current to direct current that can be used in place of the battery or can be used to charge the battery associated with the power supply 140. In another example embodiment, the information handling system 100 is designed to run primarily on alternating current. These types of systems, such as a desktop computer or the like, include a power supply that transforms current from an alternating current source to voltage at a level for delivery to the central processing unit 104, the random access memory 132, and the read only memory 134. In some embodiments, the power supply 140 also supplies power at a specific level to one or more of the peripherals 112, 114, 116, 118, 120, 122.

It should be noted that the information handling system or computer system 100 described above is one example embodiment of a computer system. Other computer systems can include multiple central processing units and multiple memory units.

In some example embodiments, the information handling-system or computer system 100 is equipped with a power management program. Many mobile computer systems implement a power management program to conserve power and extend battery life as consumers generally prefer mobile computing systems with longer battery life. Desktop computers and other computers also may implement a power management program. In a computing system 100 that implements a power management program, one or more of the various devices or components of the computer system 100 are power management enabled. Any device or component of the computer system 100 can be power management enabled. For example, the central processing unit 104, the random access memory 132 and the read only memory 134 can be power management enabled. A video card, which is an interface between the central processing unit and a monitor, can also be power management enabled. Another peripheral device that can be power management enabled is a printer. In other words, one or more of the devices or components of the information handling system or computer system 100 include provisions through which a power management enabled operating system can put some or all of these devices or components into low-to-no function power saving modes. The devices or components are brought back to the full function normal power consumption mode of operation when the devices or components are needed.

Examples of these computer systems include ACPI compliant systems equipped with Windows 95® or later (available from Microsoft Corp. of Redmond, Wash.). ACPI compliant means compliance with the Advanced Configuration and Power Interface specification, revision 1.0 or later, available from Intel Corp. of Santa Clara, Calif., a co-developer of the specification, and assignee of the present application.

In order to most effectively execute a power management program for the computer system 100, an accurate estimation or determination of the power consumption of at least one of the devices or components of the information handling system or computer system 100 is necessary. Generally, the total amount of power used by a device or component includes active power used by a component or device, and also includes leakage power consumed by a component or device. The active power is the amount of power used when the component or device is active or operating. Leakage power results from leakage current. Leakage current is inherent in devices or components that include transistors. Leakage current is current that conducts through a transistor even when the transistor is supposed to be off. Leakage current consumes power without producing useful work. As a result, the amount of active power used by a component cannot be used alone to project the total energy dissipated by a component or device, such as a microprocessor. Power comsumption includes not only the active power used by a component or device, but also includes the leakage power consumed by a component or device.

Leakage power for a die or device that includes a plurality of transistors is a function of the voltage applied to the device, also known as supply voltage, and the die or device temperature. The functional relationship can be stated generally as follows:
P_{LEAK}=f(Vₙ,Tₘ)
P_{LEAK} is the amount of power that is dissipated due to leakage current at a given time. The amount of energy that is dissipated over a span of time is the summation of the various P_{LEAK} values at the various times. The functional relationship can be stated generally as follows:
E_{LEAK}=Σf(Vₙ,Tₘ)
During the operation of a die or device, the temperature of the die or device varies continuously. For example, the voltage applied to a central processing unit varies over time due to the varying current demand in the processor and due to dynamic voltage scaling for power and thermal management. The die temperature of the central processing unit varies as a function of the active power and leakage power dissipated by the central processing unit, as well as the type of workload. In addition to having various voltages applied to a component and having fluctuating temperatures on the die or device, the die or device can have areas that tend to operate at higher temperatures than other areas of the die or device. These areas are generally known as hot spots. Thus, the amount of leakage power varies continously over time and also varies with respect to the area of the die or device. To estimate or determine the leakage power associated with a particular component or device, the temperature and voltage values must be measured on the component or device.

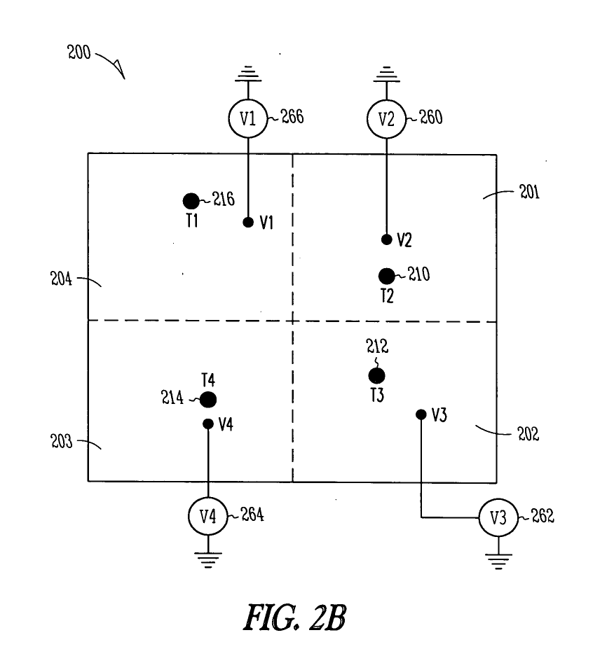

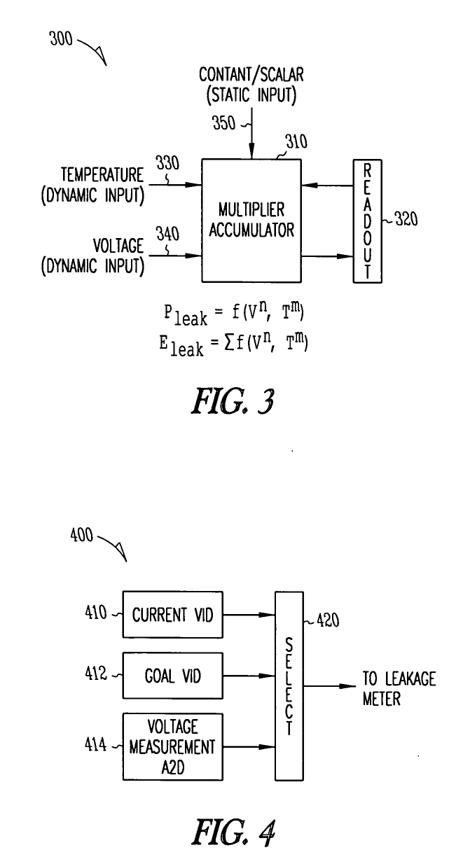

FIG. 2A is a schematic view of a component or device 200 that includes a plurality of temperature sensors, such as a temperature sensor 210, a temperature sensor 212, a temperature sensor 214, and a temperature sensor 216, according to an example embodiment. The die or device 200 is segmented or divided into parts or portions 201, 202, 203, 204, as depicted by the dotted lines. The temperature sensor 210 is placed with the portion 201 of the die or component 200. The temperature sensor 212 is placed with the portion 202 of the die or component 200. The temperature sensor 214 is placed with the portion 203 of the die or component 200. The temperature sensor 216 is placed with the portion 204 of the die or component 200. The portions 201, 202, 203, 204 of the die or device or component 200 are equal in the example shown in FIG. 2A. It should be understood that any number of portions of the die or device or component can be selected. It should also be noted that the portions selected need not be equal.

The voltage being applied to the component or device 200 is measured by the voltage sensor 220. In some embodiments, the voltage sensor 220 is off the device or component 200. As shown in FIG. 2A, the voltage sensor 220 is measuring the voltage applied at two pins associated with the component or device 200. The voltage sensor 200 could be a voltmeter or the like. In other embodiments, the voltage sensor 220 is on the die or device or component. In still other example embodiments, the semiconductor device also includes a first sensor for sensing a voltage being applied to a first selected portion of the semiconductor device, and a second sensor for sensing a voltage being applied to a second selected portion of the semiconductor device.

FIG. 2B is a schematic view of a component or device 250 that includes a plurality of temperature sensors, and a plurality of voltage sensors, according to an example embodiment. The component or device 250 includes a temperature sensor 210, a temperature sensor 212, a temperature sensor 214, and a temperature sensor 216. The component or device 250 includes a voltage sensor 260, a voltage sensor 262, a voltage sensor 264, and a voltage sensor 266. The die or device 250 is segmented or divided into parts or portions 201, 202, 203, 204, as depicted by the dotted lines. The temperature sensor 210, and the voltage sensor 260 are placed with the portion 201 of the die or component 250. The temperature sensor 212, and the voltage sensor 262 are placed with the portion 202 of the die or component 250. The temperature sensor 214, and the voltage sensor 264 are placed with the portion 203 of the die or component 250. The temperature sensor 216, and the voltage sensor 266 are placed with the portion 204 of the die or component 250. The portions 201, 202, 203, 204 of the die or device or component 250 are equal in the example shown in FIG. 2B. It should be understood that any number of portions of the die or device or component can be selected. It should also be noted that the portions selected need not be equal.

The voltage applied to the various portions 201, 202, 203, 204 of the component or device 250 is measured by the various voltage sensors 260, 262, 264, 266. In some embodiments, the voltage sensors 260, 262, 264, 266 are off the device or component 250. In other embodiments, the voltage sensors 260, 262, 264, 266 are on the die or device or component 250. The voltage sensors 260, 262, 264, 266 are measure the voltage of a portion of the device or component with respect to a reference voltage. As shown in FIG. 2B, the voltage sensors 260, 262, 264, 266 are measure the voltage with respect to ground. As shown in FIG. 2B, the semiconductor device includes at least a first sensor for sensing a voltage being applied to a first selected portion of the semiconductor device, and a second sensor for sensing a voltage being applied to a second selected portion of the semiconductor device.

FIG. 3 is a schematic view of a leakage meter 300, according to an example embodiment. The leakage meter 300 includes a multiplier and accumulator 310 and a readout register 320. Input to the multiplier and accumulator 310 is a dynamic temperature input 330, a dynamic voltage input 340, and a constant scalar input 350. The temperature and voltage will be sampled from the voltage sensor 220 and from the on-die temperature sensors 210, 212, 214, 216. The sampling rate will be determined mainly by the rate of change of the voltage and temperature inputs and also by the desired accuracy in the final leakage power measurement. At a selected sample time, each of the temperature sensors 210, 212, 214, 216 inputs a temperature reading to the multiplier and accumulator 310. Also input to the multiplier and accumulator 310 is a reading from the voltage sensor 220. In the embodiment shown in FIG.3, the voltage sensor 220 will provide the same sensed voltage. A constant/scalar input 350 is constant for each sample is also input to the multiplier and accumulator 310. The constant/scalar is generally computed as a part of the production testing and characterization of the die or device or component, such as a central processing unit. Any other constants and scalars needed for the power leakage computation are either hardcoded in the multiplier and accumulator 310 or supplied via fuses and control registers. Using the acquired data inputs, the multiplier and accumulator 310 determines the amount of power leakage for the first portion 201, the amount of power leakage for the second portion 202, the amount of power leakage for the third portion 203, and the amount of power leakage for the fourth portion 204. After the leakage power for each of the portions 201, 202, 203, and 204 is determined, the separate power leakage values are summed to produce the leakage power for the die or device. This is repeated for all of the various devices or dies or components in the information handling system or computer system 100 (see FIG. 1) for which the leakage power is desired. The leakage power for each of the die or components or devices in the information handling system or computer system 100 is accumulated or summed to arrive at a determination or estimation of the total leakage power for the information handling system or computer system 100 (see FIG. 1). FIG. 3 shows one configuration of a multiplier and accumulator 310. Of course, the multiplier and accumulator implementation can vary depending upon the accuracy requirements and resource constraints. It is contemplated that the ability to configure the scalars and constants input 350 post-silicon will allow for further comprehension of process variations and miscorrelation.

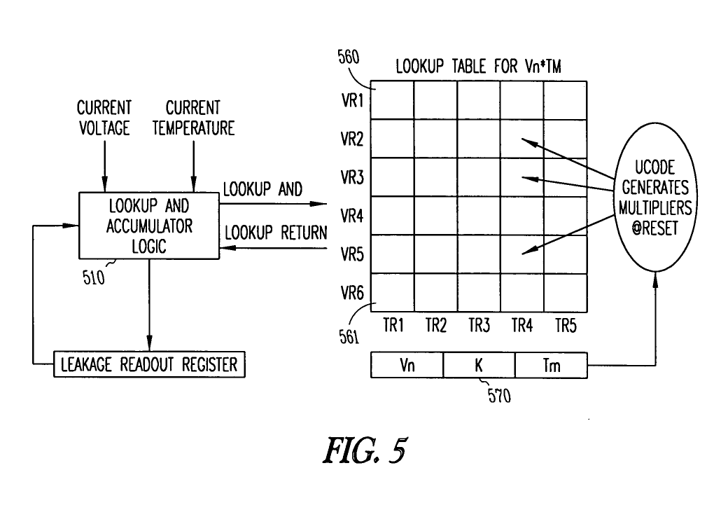

FIG. 4 is a view of a voltage input device 400, according to an example embodiment of the invention. The voltage input device 400 is used in the absence of voltage detectors and analog-to-digital converters for reading an actual voltage from a component or device, such as device 200, shown in FIG. 2. Generally a central processing unit includes voltage identification (VID) information to approximate the voltage applied to the die or device or component 200. If the VID information is used, the load line effects in the power delivery network cannot be comprehended by the leakage meter 300 (shown in FIG. 3). The load line effects can be approximated by summing at least the voltage drop (current x resistance) at all times and adjusting the voltage information accordingly. FIG. 4 shows a high level plan for voltage input to the leakage meter 300 (shown in FIG. 3). The VIDs are used, a selection can be made to pick a more appropriate VID, depending upon the state of the component or die or device 200. As shown in FIG. 4, the voltage input device 400 includes a current VIED 410, a goal VID 412 and a voltage measurement that has been turned from an analog signal into a digital signal 414. The voltage input device 400 also includes a selector 420. The selector 420 selects between the voltage measurement 414, the goal VID 412 or the current VID 410. Each of these inputs 410, 412, 414 has a voltage associated therewith. The selector 420 selects the approximate voltage and inputs the approximate voltage to the multiplier and accumulator 310 (shown in FIG. 3). The output of the voltage input device 400 is depicted by the reference numeral 440. The output of the voltage input value device 400 becomes the input voltage 340 to the leakage meter 300 (shown in FIG. 3).

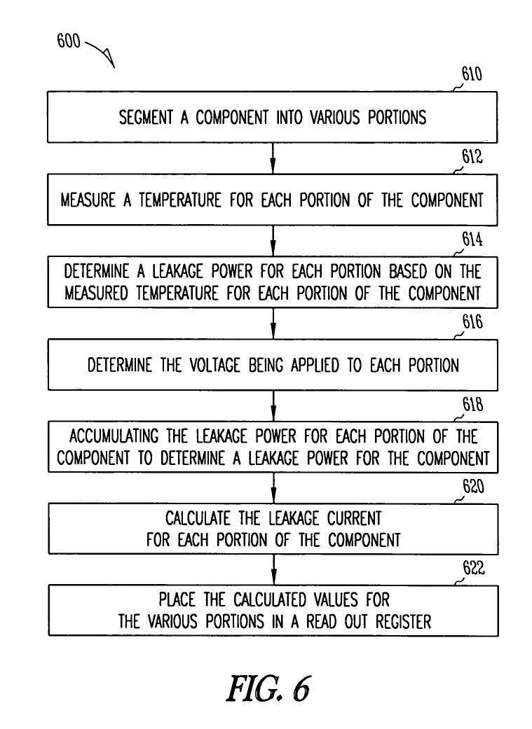

FIG. 5 is a schematic view of a multiplier and accumulator 510, according to an example embodiment. The multiplier and accumulator 310 (shown in FIG. 3) can be implemented in any number of ways. One of the ways includes calculating the leakage value given a measured voltage, a measured temperature for a portion of a device, and a fixed scalar or constant. If a calculation is made for each set of inputs at a selected sampling rate, the multiplier and accumulator 510 requires a number of computations. In other words, the number of computations can lead to a high overhead situation or a high usage situation for the multiplier and accumulator. FIG. 5 illustrates a schematic view of an implementation of a multiplier and accumulator 510 which requires less computations to yield the leakage power values. The multiplier and accumulator 510 employs a lookup table 560. The lookup table includes a number of voltage ranges, such as VR1, VR2, VR3, VR4, VR5 and VR6. The lookup table 560 also includes a number of temperature ranges including temperature TR1, TR2, TR3, TR4 and TR5. The voltage ranges VR1, VR2, VR3, VR4, VR5, VR6 cover the range of voltages which the device or die or component is suspected to operate within. Similarily temperature range for the expected operation of the component or die or device is divided into sub-temperature ranges TR1, TR2, TR3, TR4, and TR5. This results in the table lookup 560 which includes 30 different cells for the various combinations of temperature range and voltage range. For example, cell 561 is for temperatures within the range TR1 and for voltages within the range of VR6. Cell 561 is one of 30 cells. Of course it should be remembered that different granularities may be used to produce lookup tables having any desired number of ranges of temperature and any desired number of ranges of voltage. In other words, they are not limited to the lookup shown in FIG. 5. The multiplier and accumulator 510 also includes a register 570 that stores the scalar K index n for voltage and an index m for temperature. In operation the present voltage and the present temperature are input to the multiplier and accumulator 510. The present voltage is found within one of the ranges VR1, VR2, VR3, VR4, VR5 and VR6. The present temperature is found to be within one of the temperature ranges TR1, TR2, TR3, TR4 and TR5.

Once it is determined which range the present voltage is within and what range the present temperature is within. The leakage power is merely read from the appropriate cell. For example, if the present voltage is within the voltage range labeled VR6 and the present temperature input to the multiplier and accumulator 510 is within the temperature range TR1, the value for the power leakage from cell 561 is read from the lookup table 560. Other portions of the component or device are similarity measured and the table lookup 560 is used to produce the appropriate power leakage value. The power leakage value associated with each of the cells is computed at the time of reset of the component or device. At the reset time the microcode computes the Pₗₑₐₖ for each pair of voltage ranges VR1, VR2, VR3, VR4, VR5, VR6 and temperature ranges TR1, TR2, TR3, TR4, TR5. These values then populate the cells, such as cell 561.

At every sample time, the voltage and temperature will be read and used to index the lookup table 560. The data return from the lookup table is accumulated into the leakage readout register 520. If the implementation supports multiple temperature inputs corresponding to different sections of the die or component or device, the accumulator 510 performs the following math: Pₗₑₐₖ=where x is the number of temperature inputs available on the die. The scalar needs to comprehend the number of temperature inputs. A simple approximation to calculate K will be to calculate it based on the measure of leakage energy on silicon and dividing it by the number of temperature inputs. This approximation assumes that the die is divided into equal sections and one thermal sensor or temperature sensor determines the temperature of each section. If the implementation allows for programming of multiple scalars, unequal sections of the die can be allowed. The output of the accumulator 510 when filled with energy values is the accumulated energy. The average leakage power, in this case, is determined by dividing the accumulated energy by the time interval over which the energy was summed.

In another example embodiment, the table is filled with power values. When the table is filled with power values the accumulator can be eliminated. The instantaneous leakage power is read directly from the table. An accumulator can be used if the table is filled with power values to find the average leakage power. If an accumulator is present, the average leakage is calculated by dividing the accumulator output by the number of leakage power samples taken.

In another example embodiment, the values for leakage power are calculated on-the-fly. This particular embodiment is set to be a more dynamic solution. In this particular embodiment, the microprocessor, or central processing unit 104 has a portion 105 (shown in FIG. 1) which is partitioned off for operations that are lower level, less intensive tasks. In other words, a portion 105 of the microprocessor, or CPU 104 (shown in FIG. 1) is dedicated to lower level, less intensive tasks. Some refer to the lower level, less intensive tasks as housekeeping tasks. The dedicated portion of the microprocessor or CPU 104 (shown in FIG. 1) does not rely on the main portion of the CPU 104 to perform the tasks. Thus, a dedicated portion for doing the housekeeping tasks does not need to interrupt the main portion of the CPU 104. The dedicated portion 105 (shown in FIG. 1) periodically performs the determination of the power leakage value for each section 201, 202, 203, 204 (shown in FIGS. 2A and 2B). These can be calculated on-the-fly by the dedicated portion 105 of the microprocessor or CPU 104. In the embodiment where the dedicated portion 105 of the microprocessor or CPU 104 calculates the leakage power values on-the-fly, there is no need for a table. In addition, the on-the-fly calculations can be done using the specific values so that a very precise measure of leakage power is obtained for a specific selected sampling time. If an output is required in terms of energy, then the leakage power at various selected times is summed to determine the energy associated with the leakage power over a selected timeframe for each of the portions 201, 202, 203, 204 of the device or component 250. It should be noted that the on-the-fly calculation can be done on either of the component or device 200 (shown in FIG. 2A) or on the device or component 250 (shown in FIG. 2B).

In still another embodiment of the invention, a microcontroller which off the semiconductor associated with CPU 104, is provided. The dedicated microcontroller performs the lower level, less intensive housekeeping tasks. The microcontroller can also perform on-the-fly calculations of the leakage power for each of the sections 201, 202, 203, 204 (shown in FIG. 2) of the device or component, such as component 200 or component 250. The dedicated microcontroller does not need to interrupt the CPU 104 to perform the housekeeping tasks. Again, precise leakage power samples can be obtained using the dedicated microcontroller. Furthermore, if energy values are needed, the calculated values from the microcontroller can be saved to produce an indication of accumulated energy over a selected timeframe. Several potential architectures for a system have been discussed. It should be noted that other architectural arrangements can also be implemented which present a system for measuring the leakage power of one or more components in the system.

FIG. 6 is a flow diagram of a method 600 for determining the leakage power, according to an example embodiment. The method 600 includes segmenting a component into various portions 610, measuring a temperature for each portion of the component 612, determining a leakage power for each portion based on the measured temperature for each portion of the component 614, determining the voltage being applied to each portion 616, and accumulating the leakage power for each portion of the component to determine a leakage power for the component 618. Determining the leakage power for each portion of the component 614 is based on the determined voltage and the measured temperature. In some embodiments, the method 600 further includes calculating the leakage current for each portion of the component 620. The method 600 further includes placing the calculated values for the various portions in a read out register 622. In some example embodiments, segmenting the component or device 610 includes segmenting the component into substantially equal portions. In other example embodiments, the component or device is segmented into unequal portions. Segmenting a component or device into various portions 610 includes segmenting the component into portions that tend toward higher temperatures than other portions of the component.

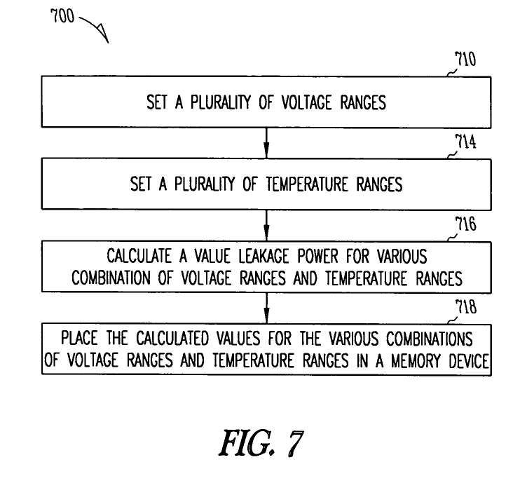

FIG. 7 is a flow diagram of a method 700 for determining the leakage power, for a number of voltage ranges and temperature ranges, according to an example embodiment. The method 700 is one example embodiment or implementation. The method 700 includes setting a plurality of voltage ranges 710, setting a plurality of temperature ranges 714, and calculating a value of leakage power for various combinations of voltage ranges and temperature ranges 716. Calculating the value of leakage power for various combinations of voltage ranges and temperature ranges 716 is done at selected times during the operation of the component. In one example embodiment, calculating the value of leakage power for various combinations of voltage ranges and temperature ranges 716 is done at reset. The method 700 further includes placing the calculated values for the various combinations of voltage ranges and temperature ranges in a memory device 718, such as a lookup table in a memory device.

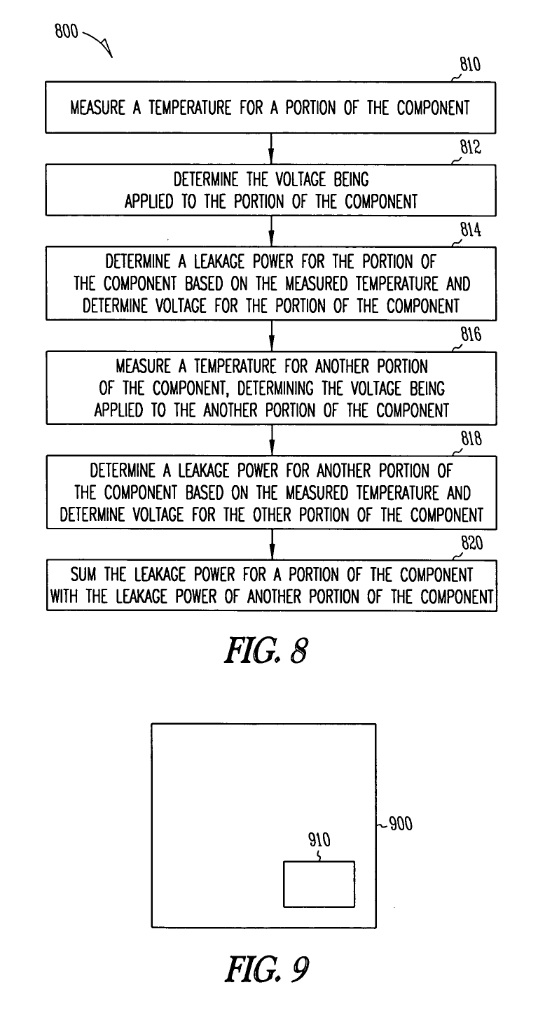

FIG. 8 is a flow diagram of a method 800 determining the leakage power, according to an example embodiment. The method 800 includes measuring a temperature for a portion of the component 810, determining the voltage being applied to the portion of the component 812, and determining a leakage power for the portion of the component based on the measured temperature and determined voltage for the portion of the component 814. The method 800 also includes measuring a temperature for another portion of the component, determining the voltage being applied to another portion of the component 816, and determining a leakage power for another portion of the component based on the measured temperature and determined voltage for the other portion of the component 818. The method 800 also includes summing the leakage power for a portion of the component with the leakage power for another portion of the component 820. Summing the leakage power for a portion of the component with the leakage power for another portion of the component 820, in some example embodiments, is included in estimating a value of leakage power for an entire component. In some example embodiments, measuring the temperature of a portion of the component 810 includes placing a sensor on the component or device. The sensor can be placed on a portion of the component or device that tends toward reaching higher temperatures than other portions of the component or device. Some example embodiments of the method 800 include selecting a plurality of voltage ranges, selecting a plurality of temperature ranges, and calculating a value of leakage power for a selected combination of a voltage range and a temperature range. The method 800 can also include selecting portions of the component or device that are substantially equal to the other portions of the component.

FIG. 9 is a schematic diagram of a machine accessible medium 900, according to an example embodiment. The machine accessible medium 900 includes a set of instructions 910. The set of instructions, when executed by a suitable information handling device such as a computer system, perform a method that includes measuring a temperature for a first portion of the component, measuring a temperature for a second portion of the component, determining the voltage being applied to the first portion of the component, determining the voltage being applied to the second portion of the component, determining a leakage power for the first portion of the component based on the measured temperature and determined voltage for the first portion of the component, and determining a leakage power for the portion of the second component based on the measured temperature and determined voltage for the second portion of the component. The method stored on the medium also includes accumulating the leakage power for the first portion of the component and the second portion of the component. In some example embodiments, accumulating the leakage power for the first portion of the component and the second portion of the component is included in determining a leakage power for the component or device. The method stored on the medium further includes sending the accumulated leakage power to a readout register. In some example embodiments, the medium includes an instruction set for performing the method on a plurality of components associated with a computer system.

A system includes a component, a voltage sensor for sensing a voltage being applied to the component, and a device for determining a leakage power. The component further includes a first temperature sensor positioned to sense a temperature associated with a first selected portion of the component, and a second temperature sensor positioned to sense a temperature associated with a second portion of the component. The device for determining a leakage power determines leakage power for the first portion of the component based on the first sensed temperature and the sensed voltage for the first portion of the component, and for the second portion of the component based on the second sensed temperature and the sensed voltage for the second portion of the component. The device for determining leakage power further includes a memory. The memory stores a value of the leakage power associated with a first portion of the component, and a value of the leakage power associated with a second portion of the component. The system also includes an accumulator for summing the determined leakage power of the first portion of the component, and the determined leakage power for the second portion of the component. The system also includes an output register for storing an accumulated value of the leakage power from a component.

It is understood that the above description is intended to be illustrative, and not restrictive. Many other embodiments will be apparent to those of skill in the art upon reviewing the above description. The scope of the invention should be, therefore, determined with reference to the appended claims, along with the full scope of equivalents to which such claims are entitled.

What is claimed is:

1. A method comprising:
segmenting a component into various portions;
measuring a temperature for each portion of the component; and
determining a leakage power for each portion based on the measured temperature for each portion of the component.

2. The method of claim 1, further comprising determining the voltage being applied to each portion, wherein determining the leakage power for each portion is based on the determined voltage and the measured temperature.

3. The method of claim 1, further comprising accumulating the leakage power for each portion of the component to determine a leakage power for the component.

4. The method of claim 2 wherein determining the leakage power further comprises:
setting a plurality of voltage ranges;
setting a plurality of temperature ranges; and
calculating a value of leakage power for various combinations of voltage ranges and temperature ranges.

5. The method of claim 4, wherein calculating a value of leakage power for various combinations of voltage ranges and temperature ranges is done at selected times during the operation of the component.

6. The method of claim 4, wherein calculating a value of leakage power for various combinations of voltage ranges and temperature ranges is done at reset, the method further comprising placing the calculated values for the various combinations of voltage ranges and temperature ranges in a memory device lookup table.

7. The method of claim 4, wherein calculating a value of leakage power for various combinations of voltage ranges and temperature ranges is done at reset, the method further comprising placing the calculated values for the various combinations of voltage ranges and temperature ranges in a lookup table.

8. The method of claim 1, wherein segmenting a component into various portions includes segmenting the component into substantially equal portions.

9. The method of claim 1, wherein segmenting a component into various portions includes segmenting the component into unequal portions.

10. The method of claim 1, wherein segmenting a component into various portions includes segmenting the component into portions that tend toward higher temperatures than other portions of the component.

11. A machine accessible medium to store a set of instructions that when executed, perform a method comprising:
measuring a temperature for a first portion of the component;
determining the voltage being applied to the first portion of the component; and
determining a leakage power for the first portion of the component based on the measured temperature and determined voltage for the first portion of the component.

12. The medium of claim 11, wherein the method further comprises:
measuring a temperature for a second portion of the component; and
determining the voltage being applied to the second portion of the component.

13. The medium of claim 12, wherein the method further comprises determining a leakage power for the portion of the second component based on the measured temperature and determined voltage for the second portion of the component.

14. The medium of claim 13, wherein the method further comprises accumulating the leakage power for the first portion of the component and the second portion of the component.

15. The medium of claim 14, wherein accumulating the leakage power for the first portion of the component and the second portion of the component is included in determining a leakage power for the component.

16. The medium of claim 14, wherein the method further comprises sending the accumulated leakage power to a readout register.

17. The medium of claim 14 for performing the method on a plurality of components associated with a computer system.

18. The medium of claim 11, wherein determining a voltage being applied to the portion of the component includes sensing a voltage value for the first portion of the component.

19. The medium of claim 11, wherein determining a voltage being applied to the first portion of the component includes sensing a voltage value applied to the component.

20. The medium of claim 11, wherein measuring the temperature of a portion of the component includes measuring the temperature of the first portion of the component.

21. The medium of claim 12, wherein measuring the temperature of the first portion of the component includes:
sensing the temperature on the first portion; and
sensing the temperature on the second portion of the component.

22. The medium of claim 11 wherein determining the leakage power further comprises:
selecting a plurality of voltage ranges;
selecting a plurality of temperature ranges; and
calculating a value of leakage power for a selected combination of a voltage range and a temperature range.

23. The medium of claim 11 wherein determining the leakage power further comprises:
determining the voltage applied to the first portion at a given time;
determining the temperature of the first portion at the given time; and
calculating a value of leakage power for a selected combination of a voltage and temperature.

24. A semiconductor device comprising:
a first temperature sensor positioned to sense a temperature associated with a first selected portion of the semiconductor device; and
a second temperature sensor positioned to sense a temperature associated with a second portion of the semiconductor device.

25. The semiconductor device of claim 24 further comprising a sensor to sense a voltage being applied to the semiconductor device.

26. The semiconductor device of claim 24 further comprising:
a first sensor to sense a voltage being applied to a first selected portion of the semiconductor device; and
a second sensor to sense a voltage being applied to a second selected portion of the semiconductor device.

27. A system comprising:
a component further comprising:
a first temperature sensor positioned to sense a temperature associated with a first selected portion of the component; and
a second temperature sensor positioned to sense a temperature associated with a second portion of the component;
a voltage sensor to sense a voltage being applied to the component; and
a device to determine a leakage power for
the first portion of the component based on the first sensed temperature and the sensed voltage for the first portion of the component; and
the second portion of the component based on the second sensed temperature and the sensed voltage for the second portion of the component.

28. The system of claim 27 wherein the device to determine leakage power further comprises a memory, wherein the memory stores a value of the leakage power associated with a first portion of the component, and a value of the leakage power associated with a second portion of the component.

29. The system of claim 27 further comprising an accumulator to sum the leakage power of the first portion of the component, and the leakage power for the second portion of the component.

30. The system of claim 29 further including an output register to store a value of the leakage power from a component, the value of the leakage power to include the leakage power of the first portion of the component, and the leakage power for the second portion of the component.
